(19) United States
(12) Patent Application Publication
(10) Pub. No.: US 2020/0025841 A1
(43) Pub. Date: Jan. 23, 2020

(54) METHOD AND SYSTEM FOR SELECTIVE RESET OF SENSORS POWERED FROM A COMMON POWER SUPPLY

(71) Applicant: GM GLOBAL TECHNOLOGY OPERATIONS LLC, Detroit, MI (US)

(72) Inventors: Timothy P. Philippart, Orion, MI (US); S.M. Nayeem Hasan, Novi, MI (US)

(21) Appl. No.: 16/040,016

(22) Filed: Jul. 19, 2018

(51) Int. Cl. G01R 33/07; B60W 20/10

(52) U.S. Cl. CPC G01R 33/072; B60W 20/10

(57) ABSTRACT

A system and method for selective reset of a sensor powered from a common power supply. The system includes a power supply, a plurality of sensors, each sensor connected to the power supply, responsive to the power supply, configured to detect a sensed parameter and provide a signal corresponding to the parameter. The system also includes a transimpedance current limiting device connected in series with a sensor of the plurality of sensors that limits current from the sensor, a switching device connected in series with the transimpedance current limiting device, that is controllable to interrupt current flow through the sensor, and a controller connected to the plurality of sensors, the controller monitors various signals from at least one sensor and controls the switching device based on those signals, wherein the controller deactivates the switching device if the current from the sensor exceeds a selected threshold.

### BACKGROUND

The subject matter disclosed herein generally relates to vehicles, powertrains, and speed sensors employed therein, and more particularly, to detection, mitigation, and reset of faults of Hall-effect speed sensors in vehicle systems that employ them.

Various powertrain architectures are known for managing the input and output torques of various prime-movers in vehicles. In conventional vehicles a internal combustion engine is typically coupled to a transmission or gear train to couple and transmit power to the drive train and thereby propel the vehicle. In hybrid applications, most commonly internal combustion engines and electric machines in series and parallel architectures are employed. Series hybrid architectures are generally characterized by an internal combustion engine driving an electric generator which, in turn, provides electrical power to an electric drivetrain and to a battery pack. The internal combustion engine in a series hybrid is not directly mechanically coupled to the drivetrain. The electric generator may also operate in a motoring mode to provide a starting function to the internal combustion engine, and the electric drivetrain may recapture vehicle braking energy by also operating in a generator mode to recharge a battery pack. Parallel hybrid architectures are generally characterized by an internal combustion engine and an electric motor which both have a direct mechanical coupling to the drivetrain. The drivetrain conventionally includes a shifting transmission to provide the necessary gear ratios for a wide range of operation.

Electrically variable transmissions (EVT) provide for continuously variable speed ratios by combining features from both series and parallel hybrid powertrain architectures. EVTs are operable with a direct mechanical path between an internal combustion engine and a final drive unit thus enabling high transmission efficiency and application of lower cost and less massive motor hardware. EVTs are also operable with engine operation mechanically independent from the final drive or in various mechanical/electrical split contributions thereby enabling high-torque, continuously variable, speed ratios, electrically dominated launches, regenerative braking, engine off idling, and multi-mode operation.

In any vehicular transmission regardless of architecture, it is commonly desirable in a transmission to measure various shaft and gear speeds as well as the rotational speed of the output shaft or a member that is ratiometrically synchronized therewith in its rotation in order to determine vehicle speed and provide needed information regarding the transmission operation for use in its control. Various technologies are known for providing such speed information including variable reluctance (VR) sensors, magneto resistive (MR) sensors, and Hall effect (HE) sensors. In all such sensors a target wheel comprising alternating regions of high and low permeability (e.g., toothed wheel) rotates in proximity to a sensing element to generate a pulse train in accordance with the target wheel rotation. For strict speed sensing where position is not a desired metric to be measured, the target wheel is generally uniform in the distribution of the high and low permeability regions. Other distribution patterns are generally reserved for encoded applications which can discern position or angular rotational information therefrom.

With respect to a transmission output, and perhaps other transmission members, accurate speed detection is desired and, while angular position generally is not, direction of rotation is a desired metric for measurement as well. As such, it is common practice to employ a pair of such sensors separated by a predetermined electrical angle which facilitates determining the speed and direction of rotation; the speed being essentially a frequency based signal and the direction being a relative event based signal.

Full range speed sensing may be critical in certain applications such as output speed sensing in a transmission. In some transmission configurations, accurate speed control itself is important and it is desirable to ensure precise measurements down to and through zero shaft/vehicle speed. In this regard, MR and HE sensors are truly zero-velocity sensors since the output signal amplitude is substantially consistent and detectible regardless of the target wheel speed whereas (VR) sensors have an output whose amplitude decreases with decreasing speed and eventually is undetectable at lower speeds. Additionally, HE and MR sensors are generally well adapted to diagnosis through direct measurement means without interfering with the speed measurements whereas VR sensors do not always lend themselves as readily to easy monitoring and automated fault detection. Some HE sensors generally rely upon an active magnetic target providing a pulsed output based on the passing of the target, while others effectively provide a current flow that is pulsed as the target passes. Advantageously these sensors lend themselves to being readily monitored and commonly employed in selected automotive speed sensing applications. However, such HE sensor may at times exhibit fault conditions which can cause them to latch or fail and may need to be diagnosed and possibly power reset to determine their functionality and ensure proper operation. Accordingly for at least the reasons discussed herein, as well as others, there is a desire to provide improved control and fault detection methods for HE sensor in motor vehicle applications.

### SUMMARY

According to one embodiment described herein is a system and method for selective reset of a sensor powered from a common power supply. The system includes a power supply, a plurality of sensors, each sensor connected to the power supply, responsive to the power supply, configured to detect a sensed parameter and provide a signal corresponding to the parameter. The system also includes a transimpedance device (resistor for example) connected in series with a sensor of the plurality of sensors that converts current from the sensor to a voltage for monitoring, a switching device connected in series with the transimpedance device, that is controllable to interrupt current flow through the sensor, and a controller connected to the plurality of sensors, the controller monitors the voltage signal from at least one sensor and controls the switching device based on the voltage signal, wherein the controller deactivates the switching device if the current from the sensor exceeds a selected threshold.

In addition to one or more of the features described above, or as an alternative, further embodiments may include operably connecting a second transimpedance device capable of limiting current in series with a second sensor of the plurality of sensors, the second transimpedance current limiting device configured to limit a second current from the second sensor of the plurality of sensors.

In addition to one or more of the features described above, or as an alternative, further embodiments may include that the second transimpedance current limiting device is a second impedance, the second impedance configured to develop a voltage thereacross based on the second current.

In addition to one or more of the features described above, or as an alternative, further embodiments may include operably connecting a second switching device in series with the second transimpedance current limiting device, the second switching device operably controllable interrupt current flow from the second sensor.

In addition to one or more of the features described above, or as an alternative, further embodiments may include the controller executing a process to monitor a second signal from the second sensor of the plurality of sensors and control the second switching device based on the second signal, wherein the controller deactivates the second switching device if the current from the second sensor exceeds a second selected threshold.

In addition to one or more of the features described above, or as an alternative, further embodiments may include that the transimpedance current limiting device is at least one of a current mirror and a resistance, the resistance configured to develop a voltage thereacross based on the current.

In addition to one or more of the features described above, or as an alternative, further embodiments may include that the resistance is less than at least one of 1000 ohms, 500 ohms, 250 ohms, and 150 ohms.

In addition to one or more of the features described above, or as an alternative, further embodiments may include the controller executing a process to reactivate the switching device within a preselected duration of time.

In addition to one or more of the features described above, or as an alternative, further embodiments may include that the preselected duration is less than at least one of 50 milliseconds, 25 milliseconds 10 milliseconds and 1 millisecond.

In addition to one or more of the features described above, or as an alternative, further embodiments may include that each sensor of the plurality of sensors is a two-wire Hall-effect sensor.

In addition to one or more of the features described above, or as an alternative, further embodiments may include that the sensed parameter is at least one of a position and speed of a component in a vehicle.

Also described herein in another embodiment is a system for selective reset of a sensor powered from a common power supply. The system includes a power supply, a plurality of sensors, each sensor of the plurality of sensors operably connected to the power supply, each sensor of the plurality of sensors responsive to the power supply and configured to detect a sensed parameter and provide a signal corresponding to the sensed parameter; and a transimpedance current limiting device operably connected in series with a sensor of the plurality of sensors, the transimpedance current limiting device configured to limit current from the sensor of the plurality of sensors. The system also includes a switching device operably connected in series with the transimpedance current limiting device, the switching device operably controllable interrupt current flow from the sensor and through the transimpedance current limiting device and a controller operably connected to the plurality of sensors, the controller executing a process to monitor the signal from at least one sensor of the plurality of sensors and control the switching device based on the signal, wherein the controller deactivates the switching device if the current from the sensor exceeds a selected threshold.

In addition to one or more of the features described above, or as an alternative, further embodiments may include operably connecting a second transimpedance current limiting device in series with a second sensor of the plurality of sensors, the second transimpedance current limiting device configured to limit a second transimpedance current from the second sensor of the plurality of sensors.

In addition to one or more of the features described above, or as an alternative, further embodiments may include that the second transimpedance current limiting device is a second impedance, the second impedance configured to develop a voltage thereacross based on the second current.

In addition to one or more of the features described above, or as an alternative, further embodiments may include operably connecting a second switching device in series with the second transimpedance current limiting device, the second switching device operably controllable interrupt current flow from the second sensor.

In addition to one or more of the features described above, or as an alternative, further embodiments may include that the controller executing a process to monitor a second signal from the second sensor of the plurality of sensors and control the second switching device based on the second signal, wherein the controller deactivates the second switching device if the current from the second sensor exceeds a second selected threshold.

In addition to one or more of the features described above, or as an alternative, further embodiments may include that the transimpedance current limiting device is an impedance, the impedance configured to develop a voltage thereacross based on the current.

In addition to one or more of the features described above, or as an alternative, further embodiments may include that the impedance is less than at least one of 1000 ohms, 500 ohms, 250 ohms, and 150 ohms.

In addition to one or more of the features described above, or as an alternative, further embodiments may include the controller executing a process to reactivate the switching device within a preselected duration of time.

In addition to one or more of the features described above, or as an alternative, further embodiments may include that the preselected duration is less than at least one of 50 milliseconds, 25 milliseconds 10 milliseconds and 1 millisecond.

In addition to one or more of the features described above, or as an alternative, further embodiments may include that each sensor of the plurality of sensors is a two-wire Hall-effect sensor.

In addition to one or more of the features described above, or as an alternative, further embodiments may include that the sensed parameter is at least one of a position and speed of a component in a vehicle.

The above features and advantages, and other features and advantages of the disclosure are readily apparent from the following detailed description when taken in connection with the accompanying drawings.

### BRIEF DESCRIPTION OF THE DRAWINGS

Other features, advantages and details appear, by way of example only, in the following detailed description, the detailed description referring to the accompanying drawings in which:

FIG. 1 depicts a motor vehicle including an internal combustion engine and motor control system according to one or more embodiments;

FIG. 2 depicts a high level block diagram of a transmission/vehicle drive system shaft speed detection scheme in accordance with one or more embodiments;

FIG. 3 depicts an example electrical circuit diagram of a speed sensing system for a motor vehicle in accordance with one or more embodiments; and

FIG. 4 is a flowchart of a method of detecting and mitigating faults in a motor vehicle speeds sensing system in accordance with one or more embodiments.

### DETAILED DESCRIPTION

The following description is merely exemplary in nature and is not intended to limit the present disclosure, its application or uses. It should be understood that throughout the drawings, corresponding reference numerals indicate like or corresponding parts and features. As used herein, the term module refers to processing circuitry that may include an application specific integrated circuit (ASIC), an electronic circuit, a processor (shared, dedicated, or group) and memory module that executes one or more software or firmware programs, a combinational logic circuit, and/or other suitable components that provide the described functionality.

Additionally, the term “exemplary” is used herein to mean “serving as an example, instance or illustration.” Any embodiment or design described herein as “exemplary” is not necessarily to be construed as preferred or advantageous over other embodiments or designs. The terms “at least one” and “one or more” are understood to include any integer number greater than or equal to one, i.e., one, two, three, four, etc. The terms “a plurality” are understood to include any integer number greater than or equal to two, i.e. two, three, four, five, etc. The term “connection” can include an indirect “connection” and a direct “connection”.

As shown and described herein, various features of the disclosure will be presented. Although similar reference numbers may be used in a generic sense, various embodiments will be described and various features may include changes, alterations, modifications, etc. as will be appreciated by those of skill in the art, whether explicitly described or otherwise would be appreciated by those of skill in the art.

The described embodiments allow for a controller to identify potential faults in a 2-wire Hall-effect sensor and selectively interrupt its supply current causing the voltage across the sensor to collapse to zero. Advantageously, the interruptions of the supply current operates to protect the hardware in the system or to reset the sensor and its internal logic in the event the sensor itself has encountered a fault. Moreover, it will be appreciated that many Hall-effect sensors may also contain learning algorithms executed at initialization to set initial conditions and gain values. If a Hall-effect sensor experiences noise (versus real signals) during these periods of initialization, (e.g., self-learning), the initialization may not be completed as expected and such sensors may behave inappropriately. As a result, to correct such a condition a re-initialization of the sensor logic may be required.

Advantageously, in the described embodiments, the interruption is executed very quickly for a predetermined amount of time sufficient to reset the sensor. Power is then reapplied to re-establish current flow and sensor re-initialization and operation. In an embodiment where the system architecture employs two-wire Hall effect sensors configured to share a common voltage supply rail, existing series isolation switching devices (e.g., FETS) are commonly employed to address a fault condition where the sensor or the input to the controller is faulted to the voltage rail. In the described embodiments, these isolation switching devices are repurposed to facilitate such interruption and resetting of the two-wire Hall-effect sensors to address other potential fault conditions. Advantageously, the described embodiments facilitate specific sensor based re-initialization to occur during all vehicle operating conditions (not just power on) while not impacting any other sensors that are powered from the same sensor supply bus.

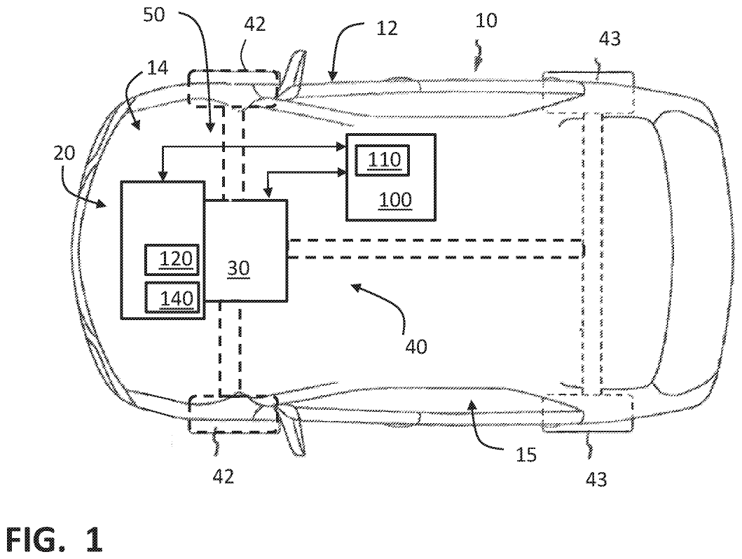

A motor vehicle, in accordance with an aspect of an embodiment, is indicated generally at 10 in FIG. 1. The motor vehicle 10 may be conventional with a gasoline fueled internal combustion engine, hybrid-electric, or all electric. In one embodiment, the vehicle 10 has a gasoline fueled internal combustion engine. FIG. 1 is a vehicle schematic showing the components of the vehicle 10 of interest with respect to the disclosed principles and the manner in which the components may be interrelated to execute those principles. It will be appreciated, however, that the illustrated architecture is merely an example, and that the disclosed principles do not require that the vehicle 10 be configured precisely as shown. It is to be understood that motor vehicle 10 may take on various forms including automobiles, commercial transports, marine vehicles, and the like. Motor vehicle 10 includes a body 12 and a passenger compartment 15. In some embodiments, the motor vehicle 10 may also include an engine compartment 14 that houses all or part of a propulsion system 50. In some embodiments, the engine compartment 14 houses an internal combustion engine system 20, which, in in some instances may be part of a hybrid implementation of the propulsion system 50. Internal combustion engine system (ICE) 20 may also include a transmission 30 mechanically coupled to a drive train 40. The drive train 40 is linked or linkable to a ground engaging drive, typically including front wheels 42 and rear wheels 43. In sonic embodiments drivetrain 40 is configured for a front wheel 42 driving application, in others a rear wheel 43 driving configuration. In some embodiments, all-wheel or four-wheel drive may be employed for the vehicle 10. For ease of illustration, a single ICE 20, transmission 30 and drivetrain 40 is depicted coupled to a single axle in a front driving configuration, but a variety of configurations are possible.

It should be noted that technical solutions described herein are germane to ICE systems 20 that can include, but are not limited to, diesel engine systems and gasoline engine systems. While the ICE system 20 may be described in a vehicular context (e.g., generating torque), other non-vehicular applications are within the scope of this disclosure. Therefore, when reference is made to a vehicle 10, such disclosure should be interpreted as applicable to any application of an ICE system 20 and possibly including a transmission 30 and drivetrain 40.

In other embodiments, the ICE system 20 may be configured to provide power to an electric drive system in a hybrid configuration. For example, in one embodiment, the ICE system 20 may be providing electric power to operate an electric propulsion system 50. In sonic embodiments, an electric propulsion system 50 and the internal ICE system 20 may he mechanically coupled to a drivetrain 40 to power the vehicle 10 (e.g., deliver tractive torque to the drivetrain 40).

Continuing with FIG. 1, in the illustrated example, the vehicle 10 and electric propulsion system 50 includes an electrical energy storage system (not shown), e.g., a battery or battery bank (“battery”) of suitable voltage and capacity. Suitable battery types include but are not limited to lead acid batteries, Nickel Cadmium batteries (NiCd), Nickel Metal Hydride batteries (NiMH), Lithium Ion batteries, and Lithium Polymer batteries. The battery is conductively linked, e.g., via a motor controller, to an electrical drive unit, (e.g., an electrical motor or motors). In some embodiments the motor controller may include a motor drive system. Typically a motor drive system may include a voltage converter, inverter, and selecting transient filtering as described below. The electrical drive unit is linked or linkable to the ground engaging drive including front wheels 42, rear wheels 43, or both. In some embodiments the electrical drive unit is a single electric motor operably connected to mechanical drive train 40, in others, multiple motors may be employed to drive an axle or wheels 42, 43 of the vehicle 10.

According to one or more embodiments, the vehicle 10 may include a controller 100 and interfaces to various sensors 120 and effectors 140 employed as part of operation of the vehicle 10. For example, the controller 100 receives from sensors 120 various input signals or values, including set point signals or values for desired output operation, such as engine speeds, transmission speeds, temperatures, pressures, control positions, torque, accelerator positions, DC bus voltages, and the like, as well as feedback signals or values representing operational values and parameters associated with various portions of the ICE system 20 and drivetrain 40. Likewise, effectors 140 may include solenoids, valves, actuators, and the like employed to operate the ICE system 20, transmission, 30 and drivetrain 40 and thereby the vehicle 10, as desired. The controller 100 may be implemented using a general-purpose microprocessor executing a computer program stored on a storage medium to perform the operations described herein. Alternatively, controller 100 may be implemented in hardware (e.g., ASIC, FPGA) or in a combination of hardware/software.

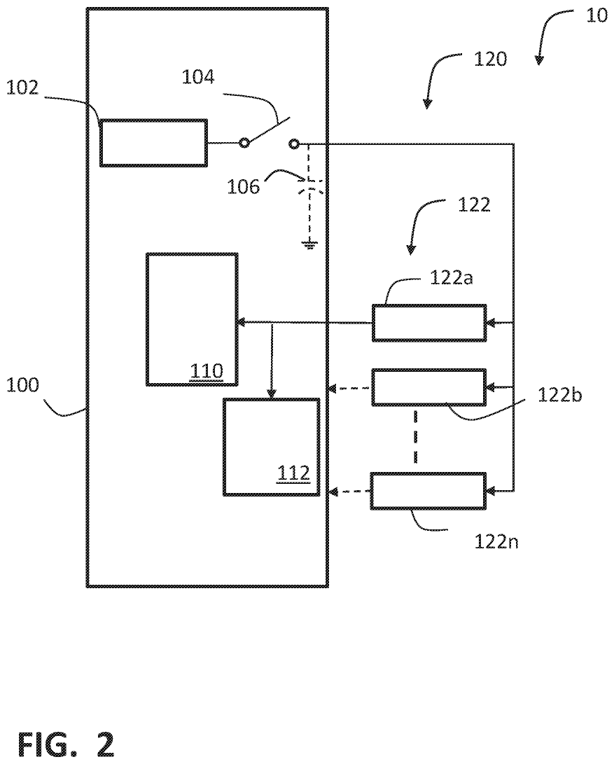

FIG. 2 depicts a simplified portion of a controller 100 interfaced with sensors 120 as required to implement the embodiments described herein. In one embodiment, the controller 100 may be interfaced to various sensors 120 to measure the speed of various components in the, vehicle 10. For example, measurement of the position and/or speed of, shafts, gears, and the like in the ICE system 20, transmission 30 and drive train 40. One such sensor 120 may include speed sensors shown generally as 122; in particular two-wire Hall-effect speed sensors denoted as 122a, 122b,-122n. Two-wire Hall-effect speed sensors 122a-122n typically exhibit two characteristics that facilitate identification and classification of faults. Typically the Hall-effect sensors output a nominal current. If the current is not present, it can be inferred that the sensor is inoperative, or the output has been shorted to ground. Similarly, Hall-effect sensors also output a pulse train. The pulses represent the passing of a target and therefore, the position and/or speed of a rotating shaft may be measured and determined.

The controller 100 may include a plurality of interfaces 110 that receive signals from sensors 120, (depicted here as sensors 122a-122n). The interfaces 110 are configured to process the signals from the various sensors 120 to be employed by the various processes of the controller 100 including, but not limited to the methodologies disclosed herein. Faults in sensors 120 can occur for numerous reasons including, but not limited to, wiring failures, short circuits, open circuits, mechanical vibration, thermal cycling, thermal shock, manufacturing defects, improper maintenance, and the like. Hall-effect sensors 122a-122n are commonly employed due to simplicity of the interface, and relative robustness. However, even with Hall-effect sensors the rapid detection and mitigation of faults is important to ensure reliable vehicle operation.

The described embodiments allow for the controller 100 to monitor the various sensors 120 via the controller interfaces 110, identify potential faults in sensors 120 (e.g., 2-wire Hall-effect sensor 122a-122n), and selectively interrupt the supply current to attempt to reset the particular sensor 122a-122n and continue operation. In an embodiment a fault disable function 112 of the controller 100 is configured to disable power supplied to one or more individual sensors 120 (e.g. one or more of 122a-122n and the like). Advantageously, with the described embodiments, the interruption is executed very quickly for a predetermined amount of time sufficient to reset the sensor 122a-122n. Power is subsequently, reapplied to re-establish current flow and sensor operation. Various architectures exist where a controller 100 can switch off or deactivate the voltage of a sensor supply bus or DC bus 102 that supplies the sensors 122a-122n. In some systems, this may be accomplished by an inline power connection device 104 controlled by the controller 100. However, typically, such a supply bus 102 might exhibit upwards of 10 uF of bulk capacitance as depicted by capacitor 106 (or even more). It is well understood that the capacitance, (e.g., capacitor 106) provides for filtering and energy storage for the voltage bus 102 and often added capacitance is advantageous. However, added capacitance 106 delays voltage changes and, as a result, for the controller 100 to disable the voltage supply on the bus 102 with the aim of resetting the Hall-effect sensors 122a-122n connected thereto, it may take upwards of 10 msecs for the voltage actually supplied to the sensors to decay sufficiently for the sensors to reset. Likewise, charging this capacitance 106 takes time as well. As a result, resetting a sensor 120, and particularly the Hall-effect sensors 122a-122n, by disconnecting the voltage bus 102 and waiting for it to discharge is not always desirable. Moreover, disabling a voltage bus (e.g., 102) that supplies a group of sensors 122a-122n as well as other sensors 120 implies that the entire group of sensors 120, or 122a-122n must be reset.

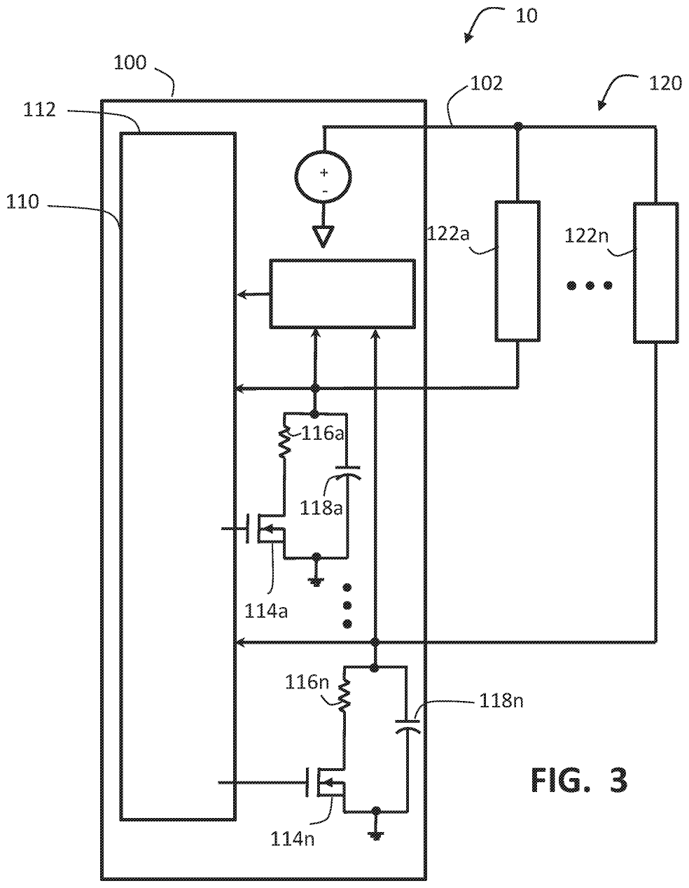

Turning now to FIG. 3, in an embodiment, the vehicle 10 includes a controller 100 and system architecture employing two-wire Hall effect sensors (e.g., 122a-122n). The two-wire Hall-effect sensors 122a-122n are configured to share a common voltage supply 102. In normal operation, the two wire Hall-effect sensors 122a-122n supply a nominal current with pulses superimposed thereon. Detection of both the nominal current and the pulse train facilitates fault detection as well as classification of the types of faults. Typically, in one configuration, this current is passed through a transimpedance device such as resistors 116a-116n, and is readily sensed by a voltage sensing function of the controller 100. Transimpedance devices 116a-116n are devices that convert current to a voltage, (e.g., current from a sensor to a voltage that is readily measurable and detectable by a controller). In an embodiment the transimpedance devices 116a-116n may include, but not be limited to a current mirror circuit, an impedance, or simply a low value resistor. A simple transimpedance device may be a resistance, while a more sophisticated transimpedance device would include a current mirror. A current mirror is generally a semiconductor device configured to mirror or match a current passed through a portion of the circuitry of the current mirror. In an embodiment, the transimpedance devices 116a-116n are configured to convert the current value to a voltage value as well as limit the current that is directed to the controller 100; particularly under fault conditions such as a short to a voltage supply and the like to facilitate the interruption of current as needed to resent the sensors 122a-122n. In an embodiment, the transimpedance devices 116a-116n are configured as low value resistors for simplicity. The low value resistor used for the transimpedance current limiting function is typically selected to be as small as possible to exhibit minimal voltage drop developed from the applied current from the Hall-effect sensor 122a-122n, yet preferably large enough to limit the amount of current passed sufficiently to avoid dissipating too much power leading to large wattage component package sizes. In one embodiment the low value resistor(s) applied as a transimpedance current limiting devices 116a-116n are in the range of around 100-250 ohms, though other values are possible; particularly depending on the voltage of the voltage supply 102. For example, values as high as 1000 ohms are possible as well as values as low as 50 ohms. However, if the transimpedance current limiting devices 116a-116n (e.g., low value resistor) are selected with too low a value, selected fault conditions will result in excessive current being driven through the transimpedance current limiting device 116a-116n, (e.g., low value resistor). As a result, excessive power would be dissipated in the transimpedance current limiting device 116a-116n unless some other method of active current limitation is used instead or in addition to having a low resistive value. This power dissipation could easily exceed the ratings for the transimpedance current limiting devices 116a-116n. One such potential fault where the sensor input to the controller 100 or the sensors 122a-122n is faulted to the voltage rail e.g., supply bus 102 or another voltage.

To address this concern, commonly higher wattage transimpedance current limiting devices 116a-116n (e.g., resistors) are employed or, simply, isolation switching devices 114a-114n are employed in series with the transimpedance current limiting devices 116a-116n to facilitate isolation under fault conditions. To that end, in an embodiment, existing isolation switching device(s) 114a-114n (e.g., FETS, transistors, and the like) corresponding to each sensor 122a-122n are repurposed and employed to address the fault condition as described herein. In an embodiment, under normal operation, the switching devices 114a-114n are conducting current developed in the Hall-effect sensor(s) 122a-122n passing through the transimpedance current limiting devices 116a-116n (e.g., resistors) to provide a conductive path to ground and subsequent voltage proportional to the amount of current flowing. Should the voltage developed across the transimpedance current limiting device(s) 116a-116n, or the current from the sensor(s) 122a-122n sensed by the controller 100 rise to a level that is beyond expected levels, it is considered a fault condition, (e.g., short in the Hall sensor 122a-122n circuit to voltage bus 102), and the like. Under such conditions, the controller 100 may elect to disable the circuit, via the switching devices 114a-114n turning off the current path and thereby isolating the particular transimpedance current limiting device(s) 116a-116n and, thereby, the affected Hall-effect sensor(s) 122a-122n. In an embodiment, the thresholds for the current and/or voltage levels will depend on several factors including, the particular type of sensor 120, the voltage level of the voltage supply 102, the transimpedance current limiting device(s) 116a-116n, and the like. For example, in an embodiment a current from the Hall-effect sensors 122a-122n is nominally on the order of 8-12 milliamps with a voltage supply 102 of 9 volts. Operation with current from the sensors of less than 4 milliamps is characterized as an open circuit and a fault, while operation with a current in excess of 18 milliamps is characterized as a fault.

Interruption of sensor supply current will cause the 2 wire Hall-effect sensors 122a-122n to enter a power reset condition and reinitialize given the collapse of voltage across the sensor pins. The described embodiments facilitate specific sensor based re-initialization to occur during all vehicle operating conditions (not just power on) while not impacting any other sensors 120 that are powered from the same sensor supply rail 102. The described sensor based re-initialization is used to correct for faults in the sensors themselves such as learning incorrect gains (AGC) or other fault based latch based mechanisms such as power line transients. In an embodiment the power is interrupted for just enough time for the affected sensor 120 to reset. Advantageously, because of the configuration of the described embodiments, the time required to implement the reset is significantly reduced maintaining control feedback during operation. In an embodiment the time to reset is on the order of less than 100 milliseconds. In some embodiments, the time for reset is less than 10 milliseconds, while in yet another embodiment, the time to reset is less than one millisecond. Conversely, interrupting current flow to a limited electrical branch or leg of the Hall-effect sensor(s) 122a-122n that need to be reset is more desirable. In this situation, advantageously, as described herein, only the capacitance associated with the leg associated with the particular affected sensor(s) 122a-122n needs to be discharged/charged when conducting the reset. The capacitance is for the individual leg is depicted by capacitor(s) 118a-118n. Such capacitor(s) 118a-118n exhibit very small capacitance, generally, on the order of 10-22 nanoFarads, which takes much less time to charge and discharge in the same circuit. As a result, the response time when removing voltage from sensors 122a-122n and reapplying to reset the sensor(s) 122a-122n is greatly improved. Moreover, disconnecting and resetting a single sensor such as 122a of 122a-122n leaves all other sensors unaffected and fully operational.

Embodiments described herein are directed to a monitoring mechanism and methodology that can detect sensor, controller and wiring failures and short circuits. In one embodiment, the methods described herein can detect and mitigate sensor faults (improper automatic gain control learning); controller voltage supply short circuits of the voltage bus 102 supplying the Hall-effect sensor(s) 122a-122n; or of the sensors 122a-122n themselves.

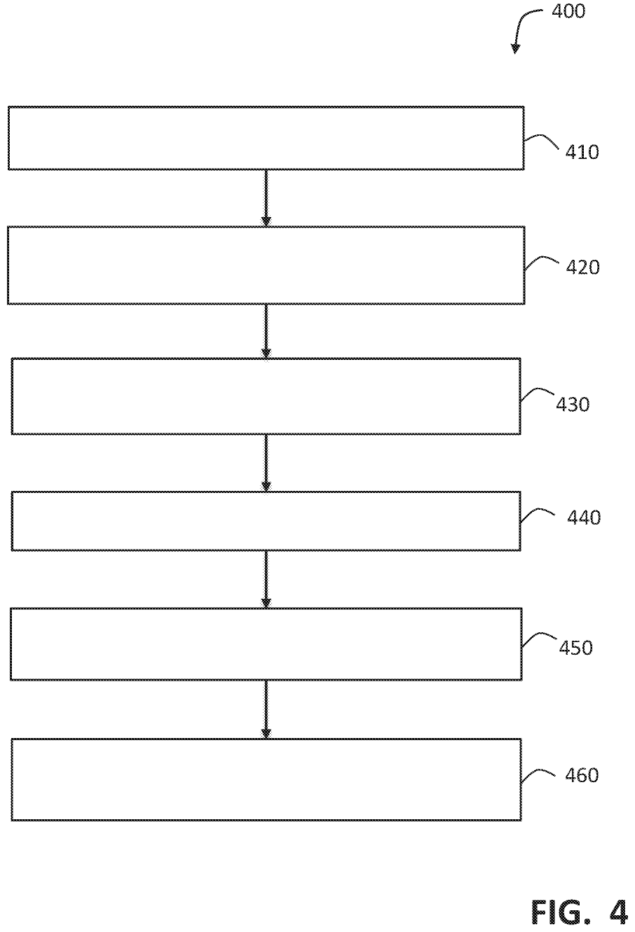

FIG. 4 is a flowchart of a method 400 for selective reset of sensors powered by a common power supply in accordance with an embodiment. One or more steps of the method 400 may be implemented by controller 100 as described herein. Moreover, some steps of the method 400 may be implemented as software or algorithms operating on the controller 100 as is conventionally known. The method 400 initiates by connecting the voltage supply 102 with each of the sensors 122a-122n as depicted at process step 410. It should be appreciated that the sensors 122a-122n could be connected to the voltage supply 102 via power connection device 104 as depicted in FIG. 2 or directly. Moreover there may be other components (e.g., sensors, current limiters, fuses and the like) between the power supply connections and the sensors 122a-122n. At process step 420 the method 400 continues with connecting a transimpedance current limiting device 116a-116n in series with the output of the sensor 122a-122n. As described herein, the transimpedance current limiting devices 116a-116n may be a current mirror circuit, or similarly functioning circuit, an impedance, or simply a resistance. In an embodiment, for simplicity, the transimpedance current limiting devices 1116a-116n are resistors. At process block 430 the process 400 continues with connecting a switching device 114a-114n in series with the transimpedance current limiting device 116a-116n. At process step 440, the output of the sensors 122a-122n are connected to a voltage sensing function of the controller 100 and a process that monitors the behavior of the sensors 122a-122n is initiated. The controller 100 monitors the behavior to ensure that the signals from the sensors 122a-122n are within expected tolerances, and the like, as depicted at process step 450. Continuing with the process 400, at process step 460, if a particular sensor (e.g., one or more of sensors 122a-122n) is not within expected range, under selected conditions, or behave in an unexpected manner, the controller 100 signals the switching device (e.g., one or more of the switching devices 114a-114n) to deactivate and thereby deactivate the particular failed sensor 122a-122n. After a selected duration, the controller 100 optionally may elect to attempt to reactivate the particular sensor 122a-122n by reactivating the respective switching device 114a-114n that was deactivated.

In this manner a process is described which permits the detection of selected sensor faults and potential mitigation of the fault by resetting the particular sensor 122a-122n. Advantageously, the process can be executed while the vehicle 10 is operational and without impacting other sensors 122a-122n that are performing properly. This provides for a highly beneficial improvement of existing schemes that typically would disable the failed sensor (e.g. one of 122a-122n) or require a long duration to reset all sensors on a particular voltage supply 102 in an attempt to mitigate a detected fault.

The terminology used herein is for the purpose of describing particular embodiments only and is not intended to be limiting. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

The present embodiments may be a system, a method, and/or a computer program product at any possible technical detail level of integration. The computer program product may include a computer readable storage medium (or media) having computer readable program instructions thereon for causing a processor to carry out aspects of the present disclosure.

The flowchart and block diagrams in the figures illustrate the architecture, functionality, and operation of possible implementations of systems, methods, and computer program products according to various embodiments. In this regard, each block in the flowchart or block diagrams may represent a module, segment, or portion of instructions, which comprises one or more executable instructions for implementing the specified logical function(s). In some alternative implementations, the functions noted in the blocks may occur out of the order noted in the Figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions.

While the disclosure has been described with reference to exemplary embodiments, it will be understood by those skilled in the art that various changes may be made and equivalents may be substituted for elements thereof without departing from its scope. In addition, many modifications may be made to adapt a particular situation or material to the teachings of the disclosure without departing from the essential scope thereof. Therefore, it is intended that the present disclosure not be limited to the particular embodiments disclosed, but will include all embodiments falling within the scope thereof.

What is claimed is:

1. A method of selective reset of a plurality of sensors powered from a common power supply, the method comprising:
operably connecting a voltage supply to each sensor of the plurality of sensors, each sensor of the plurality of sensors responsive to the power supply and configured to detect a sensed parameter and provide a signal corresponding to the sensed parameter;
operably connecting a transimpedance current limiting device in series with a sensor of the plurality of sensors, the transimpedance current limiting device configured to convert current to a voltage and to limit current from the sensor of the plurality of sensors;
operably connecting a switching device in series with the transimpedance current limiting device, the switching device operably controllable interrupt current flow from the sensor and through the transimpedance current limiting device; and
operably connecting a controller to the plurality of sensors, the controller executing a process to monitor the signal from at least one sensor of the plurality of sensors and control the switching device based on the signal, wherein the controller deactivates the switching device if at least one of the current from the sensor exceeds a selected threshold or the signal indicates that the at least one sensor exceeds an expected range.

2. The method of claim 1, further including operably connecting a second transimpedance current limiting device in series with a second sensor of the plurality of sensors, the second transimpedance current limiting device configured to limit a second current from the second sensor of the plurality of sensors.

3. The method of claim 2, wherein the second transimpedance current limiting device is a second impedance, the second impedance configured to develop a voltage thereacross based on the second current.

4. The method of claim 2, further including operably connecting a second switching device in series with the second transimpedance current limiting device, the second switching device operably controllable interrupt current flow from the second sensor.

5. The method of claim 3, further including the controller executing a process to monitor a second signal from the second sensor of the plurality of sensors and control the second switching device based on the second signal, wherein the controller deactivates the second switching device if the current from the second sensor exceeds a second selected threshold.

6. The method of claim 1, wherein the transimpedance current limiting device is at least one of a current mirror and a resistance, the resistance configured to develop a voltage thereacross based on the current.

7. The method of claim 6, wherein the resistance is less than at least one of 1000 ohms, 500 ohms, 250 ohms, and 100 ohms.

8. The method of claim 1, further including the controller executing a process to reactivate the switching device within a preselected duration of time.

9. The method of claim 8, wherein the preselected duration is less than at least one of 50 milliseconds, 25 milliseconds 10 milliseconds and 1 millisecond.

10. The method of claim 1, wherein each sensor of the plurality of sensors is a two-wire Hall-effect sensor.

11. The method of claim 1, wherein the sensed parameter is at least one of a position and speed of a component in a vehicle.

12. A system for selective reset of a sensor powered from a common power supply, the system comprising:
a power supply;
a plurality of sensors, each sensor of the plurality of sensors operably connected to the power supply, each sensor of the plurality of sensors responsive to the power supply and configured to detect a sensed parameter and provide a signal corresponding to the sensed parameter;
a transimpedance current limiting device operably connected in series with a sensor of the plurality of sensors, the transimpedance current limiting device configured to limit current from the sensor of the plurality of sensors;
a switching device operably connected in series with the transimpedance current limiting device, the switching device operably controllable interrupt current flow from the sensor and through the transimpedance current limiting device; and
a controller operably connected to the plurality of sensors, the controller executing a process to monitor the signal from at least one sensor of the plurality of sensors and control the switching device based on the signal, wherein the controller deactivates the switching device if at least one of the current from the sensor exceeds a selected threshold or the signal indicates that the sensor exceeds an expected range.

13. The system of claim 12, further including operably connecting a second transimpedance current limiting device in series with a second sensor of the plurality of sensors, the second transimpedance current limiting device configured to limit a second transimpedance current from the second sensor of the plurality of sensors.

14. The system of claim 13, wherein the second transimpedance current limiting device is a second impedance, the second impedance configured to develop a voltage thereacross based on the second current.

15. The system of claim 13, further including operably connecting a second switching device in series with the second transimpedance current limiting device, the second switching device operably controllable interrupt current flow from the second sensor.

16. The method of claim 15, further including the controller executing a process to monitor a second signal from the second sensor of the plurality of sensors and control the second switching device based on the second signal, wherein the controller deactivates the second switching device if the current from the second sensor exceeds a second selected threshold.

17. The system of claim 12, wherein the transimpedance current limiting device is an impedance, the impedance configured to develop a voltage thereacross based on the current.

18. The system of claim 17, wherein the impedance is less than at least one of 1000 ohms, 500 ohms, 250 ohms, and 150 ohms.

19. The system of claim 12, further including the controller executing a process to reactivate the switching device within a preselected duration of time.

20. The system of claim 8, wherein the preselected duration is less than at least one of 50 milliseconds, 25 milliseconds 10 milliseconds and 1 millisecond.

21. The system of claim 12, wherein each sensor of the plurality of sensors is a two-wire Hall-effect sensor.

22. The system of claim 12, wherein the sensed parameter is at least one of a position and speed of a component in a vehicle.
